(19) United States
(12) Patent Application Publication
(10) Pub. No.: US 2026/0334265 A1
(43) Pub. Date: Oct. 22, 2026

(54) SEMICONDUCTOR DEVICE PACKAGE WITH INTEGRAL MULTI-LAYER LEADS AND METHOD OF MANUFACTURING

(71) Applicant: SEMICONDUCTOR COMPONENTS INDUSTRIES, LLC, Scottsdale, AZ (US)

(72) Inventors: Olaf ZSCHIESCHANG, Sinsheim (DE); Ankit Bhushan SHARMA, Erding (DE)

(73) Assignee: SEMICONDUCTOR COMPONENTS INDUSTRIES, LLC, Scottsdale, AZ (US)

(21) Appl. No.: 19/648,719

(22) Filed: Apr. 15, 2026

Related U.S. Application Data
(60) Provisional application No. 63/789,671, filed on Apr. 16, 2025.

(51) Int. Cl. H10W 70/68; H10P 74/20; H10W 70/05; H10W 70/40

(52) U.S. Cl. CPC H10W 70/682; H10P 74/207; H10W 70/096; H10W 70/467

(57) ABSTRACT

A semiconductor device package and a method for manufacturing the same are disclosed. The semiconductor device package includes a lead frame and at least one semiconductor die attached to the lead frame. The semiconductor die and the lead frame are embedded within laminated layers of a printed circuit board (PCB), the PCB including a device portion and a lead portion. Leads extending from the device portion are formed by singulating the laminated layers of the lead portion using a milling tool. The integral, multi-layer leads include conductive layers on their respective outer surfaces that are electrically connected to the embedded components via internal micro-vias. Furthermore, the singulated leads are shaped to conform to a standardized transistor outline (TO) package footprint, such as a TO-247 footprint, providing direct compatibility with legacy automated test equipment.

### CROSS REFERENCE TO RELATED APPLICATION

This application claims the benefit of U.S. Provisional Application No. 63/789,671, filed on Apr. 16, 2025, which is hereby incorporated by reference in its entirety.

### FIELD OF THE INVENTION

The present disclosure relates to a package for qualification testing of devices (i.e., chips) in a printed circuit board (PCB) embedded package.

### BACKGROUND

Wide-bandgap (WBG) materials, such as Silicon Carbide (SiC) and Gallium Nitride (GaN), can be used in high-power automotive devices due to their ability to operate at higher switching frequencies, higher voltages, and higher temperatures. Embedded PCB packaging may be a desired package type for these applications because they can provide the power component cooling and protection without additional plastic molding or external enclosures. This is accomplished because embedded PCB packaging integrates the active power components within internal dielectric and copper layers rather than being mounted on a substrate surface. In other words, the PCB functions as both the primary carrier and the protective housing for the active device. This streamlined, integrated packaging approach can provide mechanical protection in a small footprint, dissipate heat through direct copper contact, and minimize parasitic inductance by shortening interconnect lengths.

### SUMMARY

The present disclosure generally describes a semiconductor device package that combines the enhanced thermal management, reduced parasitic inductance, and mechanical robustness of PCB embedding technology with integral, multi-layer leads shaped to conform to a transistor outline (TO) footprint, thereby enabling seamless compatibility with legacy automated test equipment.

In some aspects, the techniques described herein relate to a method for manufacturing a semiconductor device package, the method including: attaching at least one semiconductor die to a lead frame; embedding the at least one semiconductor die and the lead frame within a layered circuit (e.g., laminated layers of a printed circuit board) including a device portion and a lead portion, the at least one semiconductor die embedded in the device portion; and singulating the lead portion to form leads extending from the device portion, wherein the leads are shaped according to a transistor outline package and include conductive layers on outer surfaces of the layered circuit that are connected to the lead frame.

In some aspects, the techniques described herein relate to a semiconductor device package, including: a lead frame; at least one semiconductor die attached to the lead frame; and a layered circuit (e.g., printed circuit board including laminated layers), the layered circuit including: a device portion embedding the at least one semiconductor die and the lead frame; and leads extending from the device portion, the leads including conductive layers on respective outer surfaces that are connected to the lead frame, wherein the leads are shaped during a singulation of the printed circuit board to conform to a transistor outline package.

In some aspects, the techniques described herein relate to a method for manufacturing a semiconductor device package, the method including: attaching at least one semiconductor die to a lead frame; embedding the at least one semiconductor die and the lead frame within a layered circuit (e.g., laminated layers of a printed circuit board) including a device portion and a lead portion, the at least one semiconductor die embedded in the device portion, the embedding including: laying up one or more layers of a B-stage prepreg material; and curing the one or more layers of the B-stage prepreg material under temperature and pressure via vacuum lamination; forming internal electrical connections connecting the at least one semiconductor die and the lead frame to the conductive layers using laser-ablated, galvanically plated blind micro-vias; singulating the lead portion (e.g., the laminated layers of the lead portion) to form leads extending from the device portion, wherein the leads are shaped according to a transistor outline package and include conductive layers on outer surfaces of the layers that are connected to the lead frame; and forming micro-vias between the conductive layers, the micro-vias distributed along a length of a respective lead to provide electrical connection between the conductive layers and mechanical strength to the respective lead.

The foregoing illustrative summary, as well as other exemplary objectives and/or advantages of the disclosure, and the manner in which the same are accomplished, are further explained within the following detailed description and its accompanying drawings.

### BRIEF DESCRIPTION OF THE DRAWINGS

FIG. 1A is a top transparent view of a semiconductor device package according to a first possible implementation of the present disclosure.

FIG. 1B is a top view of a semiconductor device package according to the first possible implementation of the present disclosure.

FIG. 1C is a bottom view of the semiconductor device package according to the first possible implementation of the present disclosure.

FIG. 2A is a top transparent view of a semiconductor device package with one chip according to a second possible implementation of the present disclosure.

FIG. 2B is a top transparent view of the semiconductor device package with multiple chips according to the second possible implementation of the present disclosure.

FIG. 2C is a top view of the semiconductor device package according to the second possible implementation of the present disclosure.

FIG. 2D is a bottom view of the semiconductor device package according to the second possible implementation of the present disclosure.

FIG. 3 illustrates a first side cross-sectional view of a semiconductor device package according to a possible implementation of the present disclosure.

FIG. 4 illustrates a side view of a semiconductor device package according to a possible implementation of the present disclosure.

FIG. 5A illustrates a side, cross-sectional view of a semiconductor device package including a lead frame according to a possible implementation of the present disclosure.

FIG. 5B illustrates a side, cross-sectional view of a semiconductor device package including a lead frame isolated using organic material according to a possible implementation of the present disclosure.

FIG. 5C illustrates a side, cross-sectional view of a semiconductor device package including a lead frame isolated using ceramic material according to a possible implementation of the present disclosure.

FIG. 6A illustrates a side, cross-sectional view of a semiconductor device package including a lead frame without a cavity.

FIG. 6B illustrates a side, cross-sectional view of a semiconductor device package including a lead frame with a cavity.

FIGS. 7A-7G illustrate steps of a method for manufacturing a semiconductor device package according to a possible implementation of the present disclosure.

FIGS. 8A-8C illustrate various implementations, which can utilize the steps for manufacturing illustrated in FIGS. 7A-7G.

FIG. 9 illustrates a flow chart of a method for manufacturing a semiconductor device package according to a possible implementation of the present disclosure.

The components in the drawings are not necessarily to scale relative to each other. Like reference numerals designate corresponding parts throughout the several views.

### DETAILED DESCRIPTION

Embedded PCB packaging represents a relatively new packaging approach for power electronics. For example, high-power transistors (e.g., MOSFET and IGBT) are traditionally packaged in a transistor outline (TO) package having three or four full-metal leads for solder connection into holes on a circuit board. Internal connections between the semiconductor device (i.e., die) and the metal leads are made through wire bonds which are encapsulated in a molded body. These wire bonds can be delicate and may be vulnerable to defects during fabrication or during use. Embedded PCB packaging replaces these vulnerable wire bonds with metal-filled micro-vias, which are more mechanically robust and can offer better thermal management and circuit performance. Accordingly, it may be desirable to transition devices from traditional package types to embedded PCB packages. One technical problem with this transition, however, is that some high-volume industries, such as the automotive industry, may have test equipment and processes based on the legacy package types.

The Automotive Electrics Council (AEC) provides guidelines for testing (e.g., AEC-Q101). These guidelines outline numerous tests to ensure that electrical components operate properly in harsh conditions. Automation can prevent these numerous tests from slowing the rate of production but requires complicated and expensive test systems and fixturing. This infrastructure may be closely tied to a particular package type. For example, a particular transistor outline package (e.g., TO-247 package) may be an automotive industry standard for high-power devices. A technical problem facing the use of an embedded PCB package type for the automotive industry is adapting it to the existing test infrastructure for the transistor outline package (e.g., TO-247 package). One approach to this problem has been to mount an embedded PCB device on an adapter test board having the leads and footprint of the transistor outline package. The temporary combination could then be mounted in the test system for the qualification measurements. Unfortunately, this adapter, or “piggy-back”, approach may be prone to failures due to accidental short circuits at the connections between the device and the adapter.

To address these technical problems, an embedded PCB device is described, which approximates the footprint of a transistor outline package (e.g., TO-247 package). The embedded PCB is a multi-layered structural and electrical medium used to fully embed and encapsulate internal package components, such as the semiconductor die and the internal lead frame. A PCB is an example of the layered circuit. Specifically, the PCB can be formed from laminated layers of dielectric and conductive materials such as FR4 glass-fiber reinforced material, uncured B-stage prepreg (thermosetting) material, and internal core layers. To establish electrical connectivity, the PCB (i.e., layered circuit) utilizes internal routing layers and vias (e.g., blind micro-vias) to connect the embedded die and lead frame to outer conductive layers and surface pads. The disclosed embedded PCB device includes leads having a size/shape to match the leads of the transistor outline package, but which are built layer-by-layer instead of being full-metal. In this way, the testing may characterize the device (i.e., die) in its true environment, while also being able to integrate with systems that are expecting a particular transistor outline package footprint (e.g., the TO-247 package footprint).

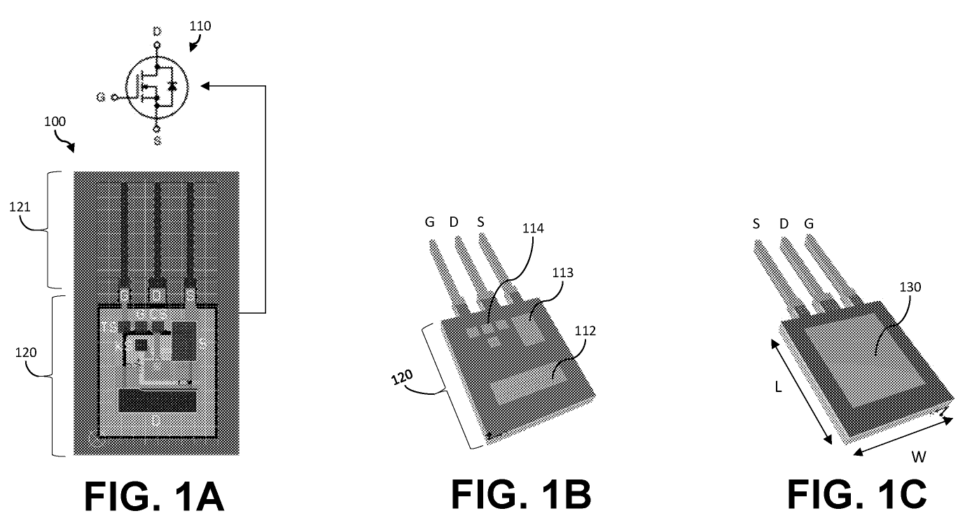

FIG. 1A is a top transparent view of a semiconductor device package (i.e., package) 100 according to a first possible implementation of the present disclosure. The semiconductor device package (i.e., package) includes a device portion 120 formed from a layered circuit including laminated layers of a printed circuit board (PCB) material, which can include the semiconductor die, which can be a metal oxide semiconductor field effect transistor (MOSFET 110). In a possible implementation, the MOSFET 110 may be fabricated from a compound semiconductor material, such as silicon carbide (SiC) or gallium nitride (GaN). The gate (G), drain (D), and source (S) terminals of the MOSFET 110 can be coupled to pads on a surface of the device portion 120 and can also be coupled to leads in a lead portion 121 of the package.

FIG. 1B is a top view of a semiconductor device package according to the first possible implementation of the present disclosure. In this first implementation, the package features exactly three leads, which correspond to a gate lead (G), a drain lead (D), and a source lead (S), which connect to the respective terminals of the MOSFET 110. The top surface of each lead has a conductive layer that runs the length of the lead but does not extend into the device portion 120. In a possible implementation, this conductive layer is a metallic plating, such as electroless nickel immersion gold (ENIG) plating, electroplated gold, or electroplated silver, immersion tin, or nickel.

The top surface of the device portion 120 further includes a plurality of electrically conducting pads disposed on its outer surface (i.e., top surface). The surface pads provide external testing and contact points that correspond to the embedded device. The pads can include a gate pad 114, a source pad 113, and a drain pad 112. Additionally, in possible implementations, the pads may further include a current sensor pad (CS), a thermal sensor pad (TS), and a Kelvin sensor pad (KS).

FIG. 1C is a bottom view of the semiconductor device package according to the first possible implementation of the present disclosure. As illustrated, the bottom surface of the device portion 120 includes a large, exposed conductive pad. Depending on the specific application or testing requirements, this exposed backside pad can be configured as either isolated or non-isolated from a lead frame of the device. As used herein, the term “lead frame” refers to an internal structure, which can be solid metal (e.g., copper), that serves as the primary physical support, thermal spreader, and electrical base for the semiconductor die within the embedded package.

In a non-isolated configuration, the bottom surface pad (i.e., back surface pad, bottom pad 130) is a (thick) copper layer that serves as a direct electrical and thermal connection to a lead frame within the package. This bottom pad 130 can provide heat spreading and allow the package to act as a direct replacement for (i.e., have the same footprint as) a TO-247 package.

Alternatively, in an isolated configuration, an internal isolation layer can electrically isolate the internal lead frame from this bottom pad 130. This isolation prevents high voltages (e.g., 1200 volts) from reaching the external surface, allowing the bottom pad to act as a ground pad and be safely mounted directly to an external heat sink.

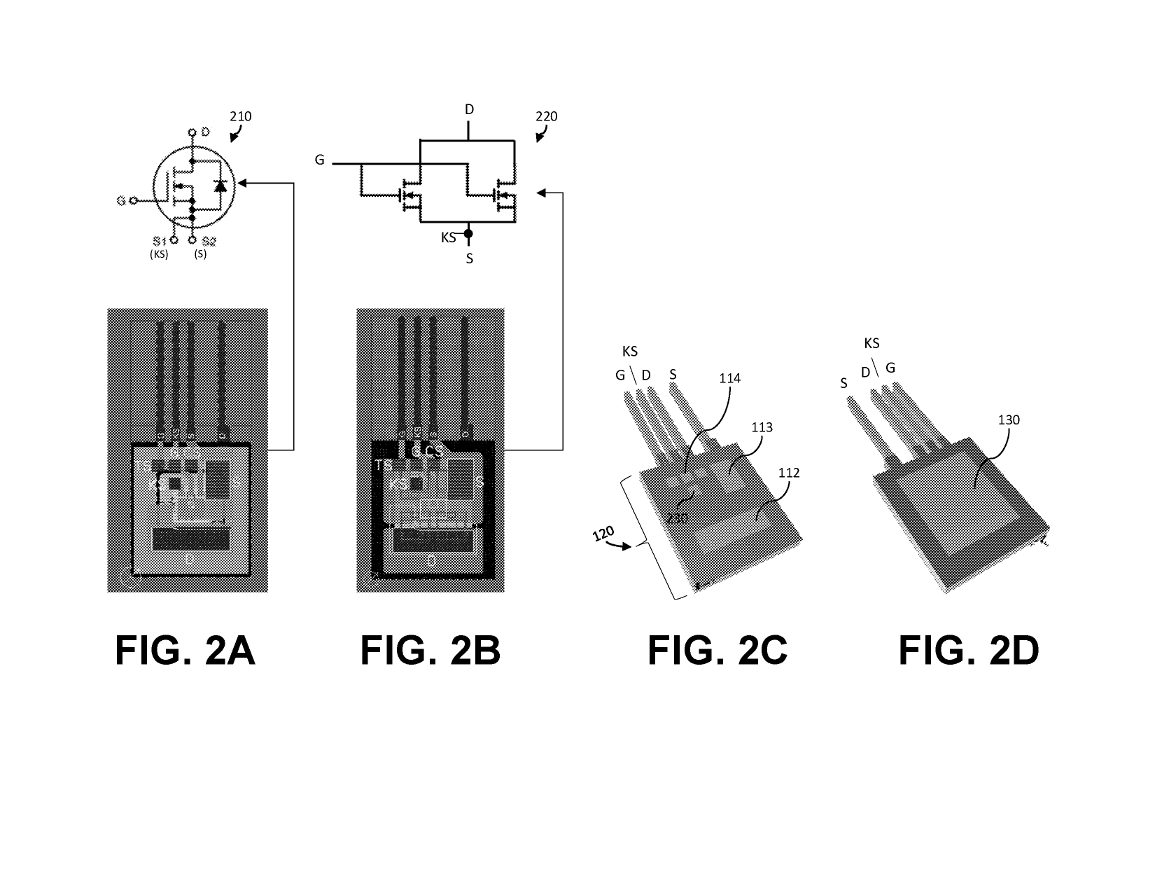

FIG. 2A illustrates a top transparent view of a semiconductor device package with one chip according to a second possible implementation of the present disclosure. Similar to the first implementation, the semiconductor device package includes a layered circuit including a device portion and a lead portion. The device portion can be formed from laminated layers of a printed circuit board (PCB) material that houses a single embedded semiconductor die. However, in this second implementation, the package features four integral, multi-layer leads extending from one side of the device portion instead of three leads.

These four leads can be singulated (i.e., formed) using a milling tool to conform to a standardized 4-lead transistor outline package footprint (e.g., TO-247 footprint) and can provide connection to a gate terminal (G), a Kelvin source (KS) terminal, a source (S) terminal, and a drain (D) terminal of a four-terminal MOSFET 210. The inclusion of the additional Kelvin Source (KS) lead is specifically configured to provide optimized switching performance during device characterization or when used in a real-world application.

FIG. 2B illustrates a top transparent view of a semiconductor device package with multiple chips according to a possible implementation of the present disclosure. Similar to the single-chip implementation shown in FIG. 2A, this multi-chip variant includes a device portion formed from laminated layers of a printed circuit board material with integral, multi-layer leads extending from one side. The multiple devices could be implemented as bare devices on a lead frame or as a subassembly package of parallel-connected devices (e.g., four devices in a PLP). These four leads are singulated using a milling tool to conform to a standardized 4-lead transistor outline package footprint, and can provide connection to a gate terminal (G), a Kelvin source (KS) terminal, a source (S) terminal, and a drain (D) terminal of a multi-chip MOSFET 220.

FIG. 2C is a top view of the semiconductor device package according to the second possible implementation of the present disclosure.

As shown in the top perspective view, the semiconductor device package includes a device portion 120 with four integral, multi-layer leads extending from one side. These leads can have the same material and the layers of the device portion 120 are milled (i.e., cut, carved) to conform to a 4-lead transistor outline (TO) package footprint (e.g., TO-247 footprint). The four leads correspond to a Gate (G) lead, a Drain (D) lead, a Source (S) lead, and a Kelvin Source (KS) lead. The top surface of the device portion further illustrates a plurality of electrically conducting surface pads (i.e., drain pad 112, source pad 113, gate pad 114, and a Kelvin source pad 230) that are connected to the internal routing and provide an alternate connection to the terminals of the multi-chip MOSFET 220.

FIG. 2D is a bottom view of the semiconductor device package according to the second possible implementation of the present disclosure. As shown in the bottom perspective view, the bottom surface of the device portion includes a large, exposed conductive pad or thermal pad (i.e., bottom pad 130). Consistent with the previously described 3-lead implementation, this exposed backside pad can be manufactured in a non-isolated configuration utilizing a thick copper slug to provide direct thermal and electrical connection to the internal lead frame, which improves heat spreading and serves as a direct TO-247 replacement. Alternatively, the package can be manufactured in an isolated configuration where an internal isolation layer, such as an organic thermal prepreg or a ceramic-based substrate, electrically isolates the internal lead frame and embedded semiconductor die(s) from the exposed bottom pad.

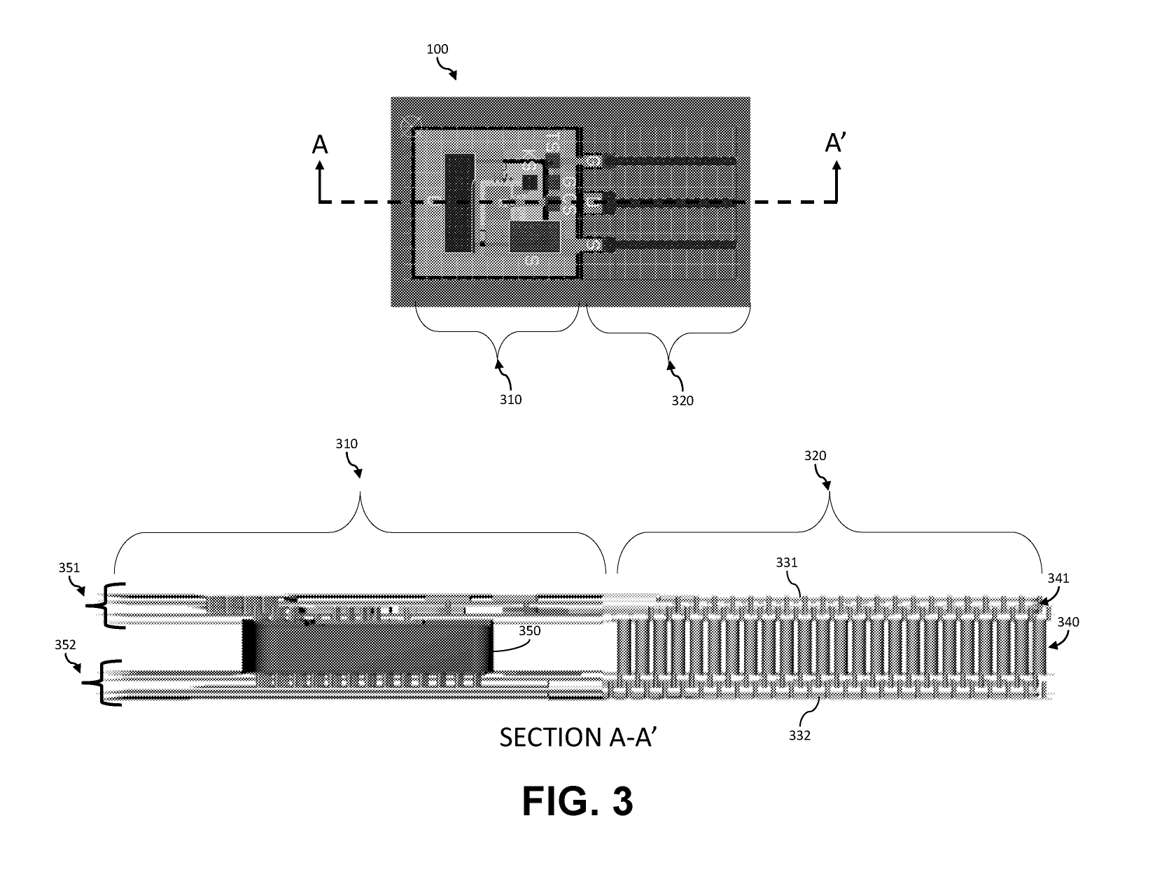

FIG. 3 illustrates a first side cross-sectional view of a semiconductor device package according to a possible implementation of the present disclosure. In particular, a top view and a corresponding side cross-sectional view taken along section line A-A', of a package 100 is shown. As depicted by the section line A-A', the cross-section cuts in the lead direction through both the device portion 310 and the lead portion 320 of the package 100.

The device portion 310 includes at least one semiconductor die (not shown) and a lead frame 350. In this specific illustrated implementation, the lead frame 350 includes a recessed cavity, and the semiconductor die is attached within this cavity. Both the semiconductor die and the lead frame 350 are completely embedded within laminated layers of a printed circuit board, which are not shown in the section view A-A’ for clarity.

As shown in the lead portion 320 of the section A-A’, the leads are layered (i.e., not solid metal). Each lead can include a plurality of vias 340 distributed (e.g., equally distributed) along a length of the lead to provide mechanical strength (e.g., rigidity). The vias 340 may also provide a connection between conductive layers on an upper surface 331 and a lower surface 332 of the lead. Collectively, the upper and lower conductive surfaces may be referred to as the outer surfaces of the lead.

As shown, additional structure may exist between the upper surface 331 and the lower surface 332. For example, the lead frame 350 may be positioned between (i.e., embedded within) a first set of laminated layers (i.e., upper layers 351) and a second set of laminated layers (i.e., lower layers 352). The upper and lower layers may include vias that are much smaller than the plurality of vias 340 used for strengthening the leads. Each of these vias may be referred to as a micro-via 341 because they can have diameters that are less than 100 micrometers. As shown, the micro-vias may also be distributed along the length of the lead to provide connection and mechanical strength. Some micro-vias may be used to connect the semiconductor die to a pad on an outer surface of the package. The upper layers 351 and lower layers 352 may be separated by a height of the lead frame 350 and a PCB core (not shown). As shown, the leads can include conductive layers on the outer surfaces of the leads. The leads can also include conductive layers within the layers of the leads. This may be useful for handling high currents. For example, a lead may include six metal layers (i.e., four inside and one on each outer surface). In another possible implementation, one or more of the leads may only have a conductive layer on one outer surface of the lead. Galvanically plated micro-vias or through-holes (or a combination thereof) can be used to establish the electrical connection between the multiple layers of the leads and provide mechanical stability.

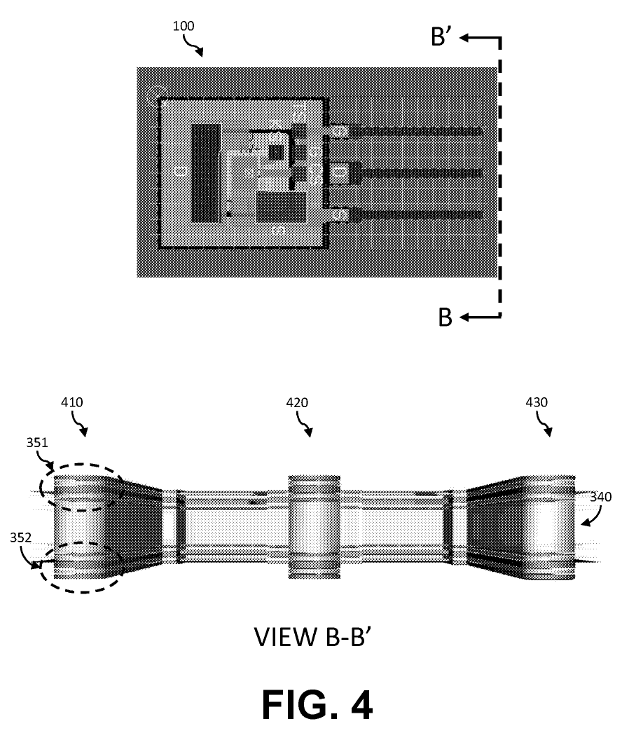

FIG. 4 illustrates a side view of a semiconductor device package according to a possible implementation of the present disclosure. In particular, a top view and a corresponding side view taken according to view line B-B', of a package 100 is shown. As depicted by the view line B-B', the view is in a direction facing the lead portion 320 of the package 100 and shows a first lead 410, a second lead 420, and a third lead 430 of the package 100. Additionally, the upper layers 351, the lower layers 352, and the plurality of vias 340 are shown.

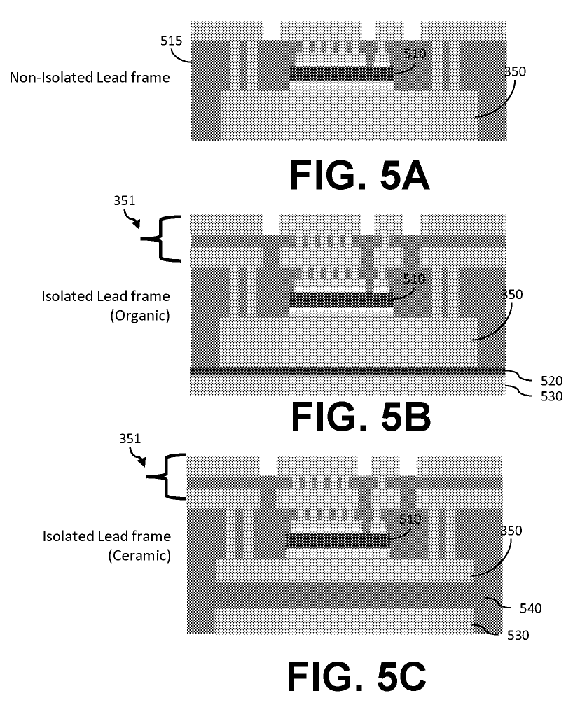

FIGS. 5A-5C illustrate side cross-sectional views of the semiconductor device package, demonstrating various internal isolation configurations for the lead frame 350.

FIG. 5A shows a semiconductor device package including a non-isolated lead frame according to a possible implementation of the present disclosure. In this implementation, the lead frame 350 is a metal (e.g., copper) block that supports a semiconductor die 510 and extends directly to the bottom surface of the package to serve as an exposed backside thermal or conductive pad. The lead frame 350 is embedded within laminated layers of a printed circuit board material 515, such as an FR4 material. This non-isolated implementation can provide improved heat spreading and serves as a direct drop-in replacement for a TO-247 package, where the backside typically operates at the drain potential.

FIG. 5B illustrates a side, cross-sectional view of a semiconductor device package including a lead frame isolated using organic material according to a possible implementation of the present disclosure. The isolated configuration includes an organic isolation layer 520 (i.e., polymer layer). In this variant, the internal lead frame 350 is electrically isolated from an exposed bottom conductive pad 530 by the organic isolation layer 520. This organic isolation layer 520 may comprise a thermal prepreg material to ensure both reliable electrical isolation and good thermal performance. By isolating the internal lead frame 350 from the bottom conductive pad 530, high internal operating voltages (e.g., 1200 volts) are prevented from reaching the external bottom surface. This isolation allows the bottom conductive pad 530 to safely act as a ground pad that can be mounted directly to an external heat sink.

FIG. 5C illustrates a side, cross-sectional view of a semiconductor device package including a lead frame isolated using ceramic material according to a possible implementation of the present disclosure. This isolated configuration includes a ceramic isolation layer 540. Similar to the organic variant, the internal lead frame 350 is electrically isolated from the bottom conductive pad 530. However, this implementation utilizes a ceramic-based substrate for the isolation layer 540, which is specifically selected to provide even greater improved thermal performance for high-power applications.

In both isolated variants (i.e., FIGS. 5B and 5C), the bottom conductive pad 530 is carefully structured and physically separated from the rest of the package (e.g., separated via etching) to ensure it is not electrically connected to the potential of the external leads, thereby safely maintaining the integrity of the ground potential on the backside of the package.

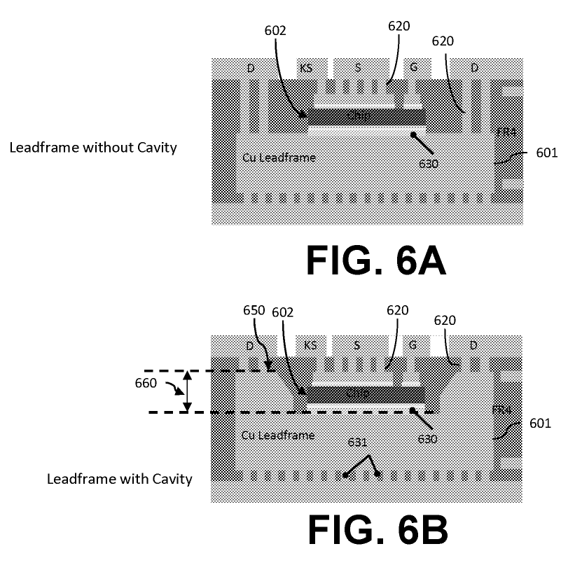

FIGS. 6A and 6B illustrate side cross-sectional views of the semiconductor device package, demonstrating two variations of the internal lead frame configuration. Specifically, FIG. 6A illustrates an implementation where the lead frame 601 is formed without a cavity, while FIG. 6B illustrates an implementation where the lead frame 601 is formed with a recessed cavity.

Both implementations share structural components. The package includes an internal (copper) lead frame. At least one semiconductor die (i.e., chip) is attached to the lead frame 601 utilizing a conductive material 630, such as a silver sinter or a conductive paste. The lead frame 601 and the semiconductor die 602 are completely embedded within laminated layers of a printed circuit board (PCB) material, such as an FR4 material. Electrical connections between the embedded components and the upper conductive layers or surface pads (e.g., gate (G), drain (D), source (S), and Kelvin source (KS) pads) are established using a plurality of laser-ablated, galvanically plated blind micro-vias 620. Alternatively, these can be implemented as galvanically plated through-holes.

FIG. 6A illustrates a side, cross-sectional view of a semiconductor device package including a lead frame without a cavity. As depicted in FIG. 6A, the lead frame 601 may be configured without a cavity (i.e., a flat profile). In this flat configuration, the semiconductor die 602 is attached directly to the top (flat) surface of the lead frame 601. Because the die 602 sits above the lead frame 601, the micro-vias 620 connecting the upper conductive layers down to the lead frame 601 can include different lengths of blind micro-vias.

FIG. 6B illustrates a side, cross-sectional view of a semiconductor device package including a lead frame with a cavity. Unlike the previous implementation, the lead frame 601 depicted in FIG. 6B includes a trench or recessed cavity which can be machined into the metal (copper) block. By attaching the semiconductor die 602 within this recessed cavity 660, the top surface of the die 602 and the adjacent top surfaces 650 of the lead frame are brought closer to the same horizontal plane. This structural variation improves overall manufacturability by allowing the micro-vias 620 to be laser-drilled to a uniform, single height across the package. The recessed cavity 660 can include a substantially flat bottom surface onto which the semiconductor die 602 can be bonded or otherwise attached. The bottom surface of the recessed cavity 660 may be sized to contain the semiconductor die 602 so that a space (i.e., gap) is formed between the semiconductor die 602 and side walls of the recessed cavity. As shown, the sidewalls of the recessed cavity can include a vertical portion that is orthogonal to the bottom surface and a beveled portion that is at an angle with the bottom surface. The vertical portion of the sidewalls may connect to the bottom surface, while the beveled portion of the sidewalls may be between a (flat) top surface of the lead frame 601 and the vertical portion of the sidewalls. The lead frame 601 may be connected to a conductive layer at the bottom surface of the package by a plurality of micro-vias 631, which can be arrayed in a regular sequence along a dimension (e.g., width) of the lead frame 601.

The manufacturing process can be identical (or similar) for both variants, aside from the initial step of creating the cavity in the lead frame 601 and adjusting the laser-drilling parameters to account for the varying micro-via lengths.

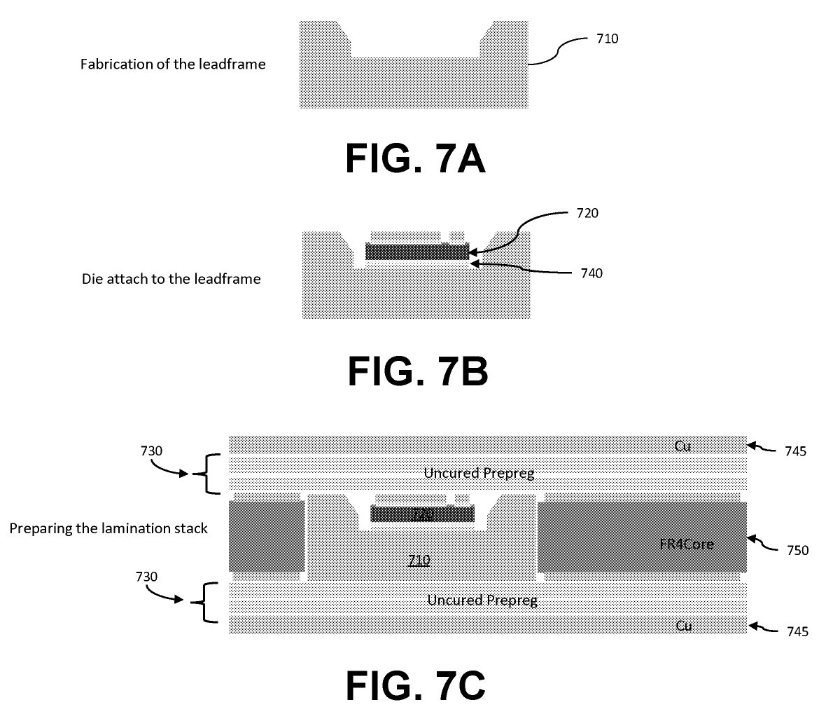

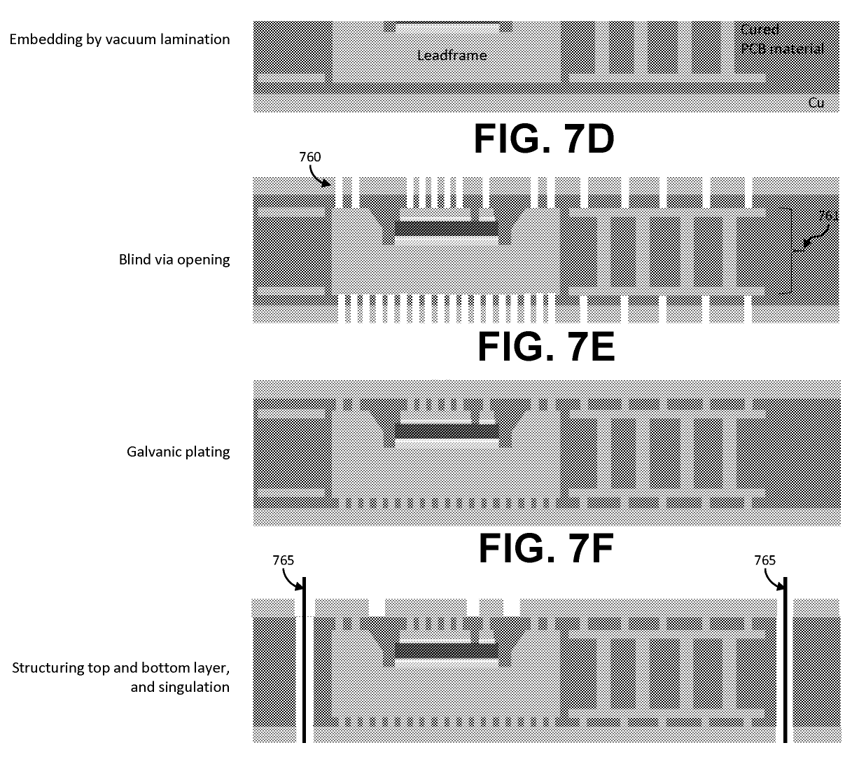

FIGS. 7A-7G illustrate steps of a method for manufacturing a semiconductor device package according to a possible implementation of the present disclosure.

FIG. 7A illustrates the fabrication of an internal lead frame 710. As detailed in various implementations of the present disclosure, this lead frame 710, which can be copper, can be manufactured with a recessed cavity or without a cavity (i.e., flat) depending on the desired micro-via lengths and manufacturer preferences.

FIG. 7B illustrates the step of attaching at least one semiconductor die 720 to a lead frame 710. The semiconductor die 720, which may be a power device, such as a power MOSFET, IGBT, or diode. The semiconductor die 720, which can be fabricated using a semiconductor such as silicon, silicon carbide, or gallium nitride, is attached to the lead frame 710 using a conductive material 740 on the bottom side of the semiconductor die 720. This conductive material 740 can comprise a silver sinter, a solder, or a conductive paste, which immediately establishes an electrical and thermal connection between the semiconductor die 720 and the lead frame 710. The semiconductor die 720 may include conductive pads at a top surface.

FIG. 7C illustrates the preparation of a lamination stack for embedding the at least one semiconductor die and the lead frame within laminated layers of a printed circuit board. This stackup step involves laying up one or more layers of an uncured, thermosetting PCB material, referred to as B-stage prepreg material 730, around the internal components on a larger manufacturing panel. To ensure proper physical alignment during this buildup, a core layer 750 may be utilized within the stack. This core layer 750 comprises cured printed circuit board material where a first height of the core layer is approximately the same as a second height of the lead frame. The core layer 750 and the lead frame 710 are positioned between layers of the B-stage prepreg material 730, and the layers of the B-stage prepreg material are between the outer conductive layers 745. A first plane is defined by top surfaces of the core layer 750, the lead frame 710, and the semiconductor die 720, while a second plane is defined by bottom surfaces of the lead frame 710 and the core layer 750.

FIG. 7D illustrates the completion of the embedding process by curing the one or more layers of the B-stage prepreg material 730 under temperature and pressure via vacuum lamination. During this process, the B-stage prepreg material 730 cures and transforms into a solid, darkened structural layer that completely integrates and protects the internal components.

FIG. 7E illustrates a blind via opening step. A plurality of via openings 760 are drilled down into the cured PCB material to expose the hidden internal layers (e.g., the die 720 and the lead frame 710) to prepare for electrical contact. Conductive layers at a top and bottom surface of the core layer 750 may be embedded internally by the vacuum lamination process. These conductive surfaces may be connected by vias 761 to provide electrical connection and mechanical stability to the lead portion of the package. While mechanical drilling is an option, these openings 760 are preferably formed using precise laser micro-drilling. The vias are referred to as blind vias because they do not penetrate the entire stack.

FIG. 7F illustrates a galvanic copper plating step. This process fills the via openings 760 to form internal electrical connections connecting at least one semiconductor die and the lead frame to conductive layers on outer surfaces of the printed circuit board using laser-ablated, galvanically plated blind micro-vias. Furthermore, micro-vias are simultaneously formed between the conductive layers in the extending lead portion of the package. As shown in the cross-section, these micro-vias are densely distributed along a length of a respective lead to provide electrical connection between the conductive layers and mechanical strength to the respective lead.

FIG. 7G illustrates the final structuring of the top and bottom conductive layers and the step of singulating the laminated layers. A milling tool is used to detach the device from the larger manufacturing panel and physically cut out the final shape of the extending multi-layer leads. The milling process ensures the leads are shaped according to a transistor outline package footprint, such as a TO-247 footprint, providing the finished unibody package with seamless compatibility with legacy automated test equipment sockets. Cuts 765 used for singulating the laminated layers to form the device portion and the lead portion are shown in FIG. 7G. These cuts for shaping and removing the semiconductor device package from the panel may be made by sawing or milling using a cutting tool or by laser ablation using a laser cutting tool.

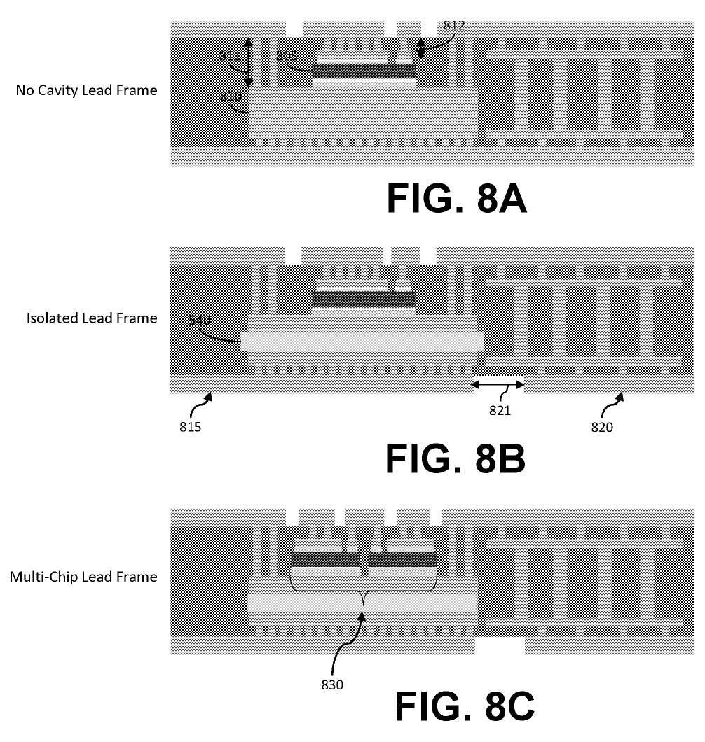

FIGS. 8A-8C illustrate various implementations, which can utilize the steps for manufacturing illustrated in FIGS. 7A-7G.

FIGS. 8A-8C illustrate side cross-sectional views of various possible implementations of the semiconductor device package that can be manufactured utilizing the process steps illustrated in FIGS. 7A-7G.

FIG. 8A illustrates an implementation utilizing a no-cavity lead frame 810. As detailed in various implementations, the overall fabrication sequence remains identical (or similar) to the process shown in FIGS. 7A-7G, except for the step of creating a cavity in the lead frame. However, because the lead frame 810 has a flat profile, the first via length 811 required to connect the top conductive layer down to the lead frame 810 increases compared to a second via length 812 of the vias connecting to the top of the embedded die 805.

FIG. 8B illustrates an isolated lead frame implementation. In this variant, the internal lead frame is electrically isolated from an exposed backside pad (e.g., a ground pad 815) by an isolation layer 540. To safely maintain the potential difference, this isolation layer 540 may comprise an organic thermal prepreg material or a ceramic material (such as SiN or Al2O3), which is integrated directly into the lamination stack during the printed circuit board buildup process. A lower conductive layer 820 on a lead may be electrically isolated from the ground pad 815 by a physical gap 821, which can be formed by etching.

FIG. 8C illustrates a multi-chip implementation. In this configuration, the lead frame is configured to accommodate a plurality of semiconductor dies 830 (e.g., up to four dies) rather than a single die. The identical (or similar) PCB embedding steps from FIGS. 7A-7G are utilized to encapsulate the plurality of semiconductor dies 830 and the lead frame within the laminated layers of printed circuit board material. Internal electrical connections between the embedded components and the outer conductive layers are then successfully established using the densely distributed laser-ablated, galvanically plated blind micro-vias.

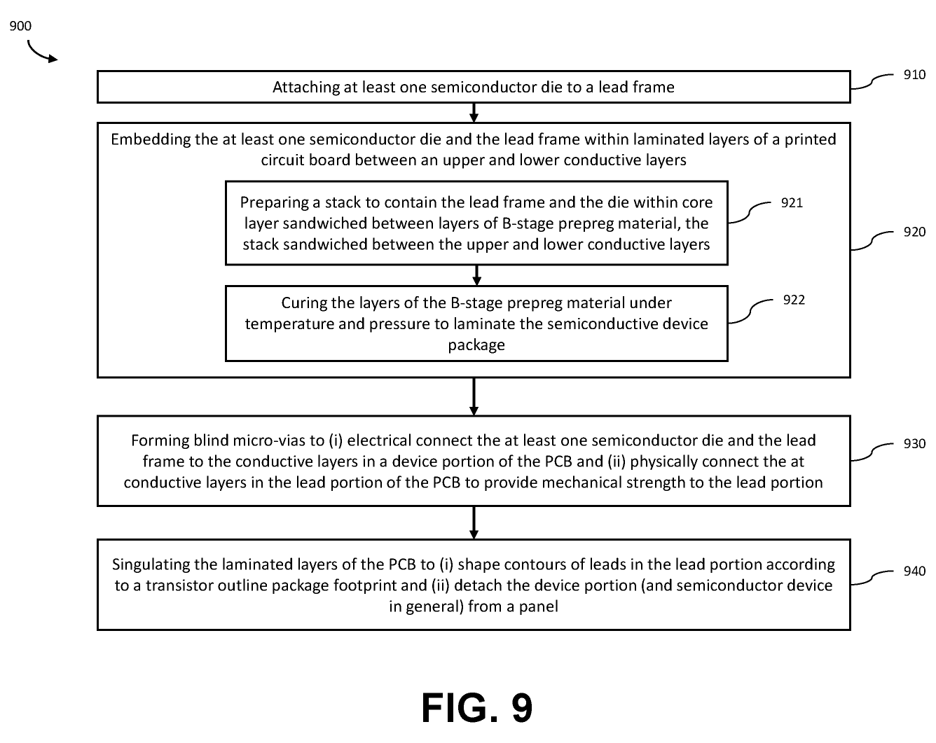

FIG. 9 illustrates a flow chart of a method 900 for manufacturing a semiconductor device package according to a possible implementation of the present disclosure.

The method 900 may begin at step 910, which comprises attaching at least one semiconductor die to a lead frame. As detailed in various implementations of the present disclosure, the lead frame may be configured with a flat profile or with a recessed cavity, and the semiconductor die (e.g., a power device such as a SiC or GaN MOSFET or IGBT) is attached utilizing a conductive material, such as a silver sinter, a solder, or a conductive paste.

At step 920, the method includes embedding the at least one semiconductor die and the lead frame within laminated layers of a printed circuit board between upper and lower conductive layers. In some implementations, this overall embedding step 920 further comprises sub-step 921 and sub-step 922. Sub-step 921 includes preparing a stack to contain the lead frame and the die within a core layer sandwiched between layers of B-stage prepreg material, the stack sandwiched between the upper and lower conductive layers. Sub-step 922 includes curing the layers of the B-stage prepreg material under temperature and pressure to laminate the semiconductor device package. As recited in the claims, this step may specifically comprise curing the B-stage prepreg material via vacuum lamination, permanently encapsulating the internal components into a solid, integrated structure.

At step 930, the method includes forming blind micro-vias to (i) electrically connect the at least one semiconductor die and the lead frame to the conductive layers in a device portion of the PCB and (ii) physically connect the conductive layers in the lead portion of the PCB to provide mechanical strength to the lead portion. This step involves forming internal electrical connections connecting the embedded components to the outer conductive surfaces utilizing laser-ablated, galvanically plated blind micro-vias. Furthermore, within the extending lead portion of the PCB, these micro-vias are densely distributed along a length of a respective lead to establish an electrical connection between the upper and lower conductive layers while simultaneously providing necessary structural rigidity and mechanical strength to the respective multi-layer lead.

By replacing wire bonds with laser-ablated, copper-filled micro-vias, the internal electrical connections are capable of handling exceptionally high-power requirements. Specifically, the structural integration of the multi-layer printed circuit board and the micro-vias allows the package to reliably handle short current pulses of up to 400 amps and continuous currents of up to 50 amps.

At step 940, the method concludes by singulating the laminated layers of the PCB to (i) shape contours of leads in the lead portion according to a transistor outline package footprint and (ii) detach the device portion (and semiconductor device in general) from a panel. This singulation process can be performed utilizing a milling tool. Crucially, the milling process ensures that the integral, multi-layer leads extending from the device portion conform to a standardized transistor outline (TO) package footprint, such as a TO-247 footprint (e.g., 3-lead or 4-lead variants with a Kelvin Source). This precise shaping provides the finished package with direct, seamless compatibility with legacy automated test equipment.

Additionally, in an alternate final configuration, the integral leads extending from the device portion may later be severed or chopped off to utilize the unibody package as a lead-less surface mount device (SMD) package after electrical testing is complete. For example, removing the extending leads forms a lead-less SMD-style package having a "Power 56" form factor or configuration. Accordingly, in a possible implementation, the method 900 may further include removing (i.e., severing) the lead portion from the package after performing electrical tests.

While certain features of the described implementations have been illustrated as described herein, many modifications, substitutions, changes, and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components, and/or features of the different implementations described.

It will also be understood that when an element is referred to as being on, connected to, electrically connected to, coupled to, or electrically coupled to another element, it may be directly on, connected, or coupled to the other element, or one or more intervening elements may be present. In contrast, when an element is referred to as being directly on, directly connected to, or directly coupled to another element, there are no intervening elements present. Although the terms directly on, directly connected to, or directly coupled to may not be used throughout the detailed description, elements that are shown as being directly on, directly connected, or directly coupled can be referred to as such. The claims of the application may be amended to recite example relationships described in the specification or shown in the figures.

As used in this specification, a singular form may, unless it definitely indicates a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC), and/or so forth.

1. A method for manufacturing a semiconductor device package, the method comprising:
attaching at least one semiconductor die to a lead frame;
embedding the at least one semiconductor die and the lead frame within a layered circuit including a device portion and a lead portion, the at least one semiconductor die embedded in the device portion; and
singulating the lead portion to form leads extending from the device portion, wherein the leads are shaped according to a transistor outline package footprint and include conductive layers on outer surfaces of the layered circuit that are connected to the lead frame.

2. The method according to claim 1, wherein the conductive layers are on opposite sides of each lead of the leads, the method further including:
forming micro-vias between the conductive layers, the micro-vias distributed along a length of a respective lead to provide electrical connection between the conductive layers and mechanical strength to the respective lead.

3. The method according to claim 1, wherein the transistor outline package footprint is a TO-247 footprint including exactly three leads or four leads, wherein the four leads include a Kelvin source lead.

4. The method according to claim 3, further comprising:
performing electrical testing on the at least one semiconductor die using automated test equipment configured to receive the TO-247 footprint.

5. The method according to claim 4, wherein the electrical testing is in accordance with Automotive Electronics Council (AEC) standards.

6. The method according to claim 4, further comprising:
severing the leads extending from the device portion to form a lead-less surface mount device (SMD) package after performing the electrical testing.

7. The method according to claim 1, further comprising:
forming a recessed cavity in the lead frame; and
attaching the at least one semiconductor die within the recessed cavity using a conductive material.

8. The method according to claim 7, wherein attaching the at least one semiconductor die within the recessed cavity using the conductive material includes:
soldering or sintering the at least one semiconductor die using silver.

9. The method according to claim 1, wherein the at least one semiconductor die includes a MOSFET or an insulated-gate bipolar transistor (IGBT), the MOSFET or IGBT fabricated from silicon carbide or gallium nitride.

10. The method according to claim 1, wherein embedding the at least one semiconductor die and the lead frame includes:
providing a core layer of cured printed circuit board, a first height of the core layer approximately the same as a second height of the lead frame;
positioning the core layer and the lead frame between layers of B-stage prepreg material; and
curing the layers of the B-stage prepreg material under temperature and pressure to laminate the semiconductor device package.

11. The method according to claim 1, further comprising:
forming internal electrical connections connecting the at least one semiconductor die and the lead frame to the conductive layers using laser-ablated, galvanically plated blind micro-vias.

12. The method according to claim 1, wherein singulating the layered circuit includes:
shaping contours of the leads using a milling tool; and
detaching the semiconductor device package from a panel using the milling tool.

13. The method according to claim 1, wherein embedding the at least one semiconductor die further includes:
forming an isolation layer between the lead frame and a ground pad on a surface of the semiconductor device package, the isolation layer including an organic material or a ceramic material.

14. A semiconductor device package, comprising:
a lead frame;
at least one semiconductor die attached to the lead frame; and
a layered circuit including:
a device portion embedding the at least one semiconductor die and the lead frame; and
leads extending from the device portion, the leads including conductive layers on respective outer surfaces that are connected to the lead frame, wherein the leads are shaped during a singulation of the layered circuit to conform to a transistor outline package footprint.

15. The semiconductor device package according to claim 14, wherein the conductive layers are on opposite sides of each lead of the leads, the semiconductor device package further including:
micro-vias formed between the conductive layers, the micro-vias distributed along a length of a respective lead to provide electrical connection between the conductive layers and mechanical strength to the respective lead.

16. The semiconductor device package according to claim 14, wherein:
the lead frame includes a recessed cavity; and
the at least one semiconductor die is attached within the recessed cavity.

17. The semiconductor device package according to claim 14, wherein the at least one semiconductor die includes a MOSFET or an insulated-gate bipolar transistor (IGBT).

18. The semiconductor device package according to claim 17, wherein the MOSFET or the IGBT is fabricated from silicon carbide or gallium nitride.

19. The semiconductor device package according to claim 17, wherein the transistor outline package footprint is a TO-247 footprint.

20. The semiconductor device package according to claim 19, wherein the TO-247 footprint includes exactly three leads or four leads, wherein the four leads include a Kelvin source lead.

21. The semiconductor device package according to claim 14, wherein the layered circuit includes:
an electrical isolation layer disposed between the lead frame and a ground pad on a side of the layered circuit, the electrical isolation layer includes an organic material or a ceramic material.

22. The semiconductor device package according to claim 14, wherein the conductive layers on the respective outer surfaces of the leads include electroless nickel immersion gold (ENIG) plating.

23. The semiconductor device package according to claim 14, wherein the at least one semiconductor die includes a plurality of semiconductor dies attached to the lead frame to form a multi-chip package.

24. The semiconductor device package according to claim 14, wherein the device portion has a length and a width of approximately 20 millimeters and approximately 22.5 millimeters, respectively.

25. A method for manufacturing a semiconductor device package, the method comprising:
attaching at least one semiconductor die to a lead frame;
embedding the at least one semiconductor die and the lead frame within a layered circuit including a device portion and a lead portion, the at least one semiconductor die embedded in the device portion, wherein the embedding includes:
laying up one or more layers of a B-stage prepreg material; and
curing the one or more layers of the B-stage prepreg material under temperature and pressure via vacuum lamination;
forming internal electrical connections connecting the at least one semiconductor die and the lead frame to conductive layers on outer surfaces of the layered circuit using laser-ablated, galvanically plated blind micro-vias;
singulating the lead portion to form leads extending from the device portion, wherein the leads are shaped according to a transistor outline package footprint and include the conductive layers on the outer surfaces of the layered circuit that are connected to the lead frame; and
forming micro-vias between the conductive layers, the micro-vias distributed along a length of a respective lead to provide electrical connection between the conductive layers and mechanical strength to the respective lead.
